(19) United States
(12) Patent Application Publication
(10) Pub. No.: US 2021/0335684 A1
(43) Pub. Date: Oct. 28, 2021

(54) MOISTUREPROOFING CHIP ON FILM PACKAGE AND METHOD OF FABRICATING THE SAME

(71) Applicant: Silicon Works Co., Ltd., Daejeon (KR)

(72) Inventors: Dam HA, Daejeon (KR); Kyung Hyun KIM, Daejeon (KR)

(73) Assignee: Silicon Works Co., Ltd., Daejeon (KR)

(21) Appl. No.: 17/238,717

(22) Filed: Apr. 23, 2021

(30) Foreign Application Priority Data
Apr. 27, 2020 (KR) 10-2020-0050645

(51) Int. Cl. H01L 23/31; H01L 21/56

(52) U.S. Cl. CPC H01L 23/3121; H01L 23/3135; H01L 23/4985; H01L 23/3192; H01L 21/56; H01L 23/3185

(57) ABSTRACT

The present disclosure discloses a moistureproofing chip on film (COF) package for protecting the conductive pattern of the COF package against moisture. The moistureproofing COF package includes a base film having a conductive pattern formed on one surface thereof and having a solder resist formed on the conductive pattern, and a moistureproofing coating layer formed on the solder resist by coating and configured to block moisture from being delivered to the conductive pattern through the solder resist.

### BACKGROUND

### 1. Technical Field

The present disclosure relates to a chip on film package (hereinafter referred to as a “COF package”), and more particularly, to a moistureproofing COF package for protecting a conductive pattern of the COF package against moisture and a method of fabricating the same.

### 2. Related Art

A display device includes a display panel, such as an LCD panel or an LED panel, and a driver integrated circuit for processing display data.

Of them, the driver integrated circuit is configured to process display data provided from the outside and to provide the display panel with an image signal corresponding to the display data. The display panel may display a screen based on the image signal of the driver integrated circuit.

In general, the driver integrated circuit is fabricated in the form of a COF package and mounted on the display panel.

The driver integrated circuit fabricated in the form of the COF package is commonly used without processing for moistureproofing. Furthermore, a solder resist applied on the COF package in order to protect a conductive pattern thereof has a low moistureproofing effect.

Accordingly, if the COF package is used in a high humidity environment, such as a vehicle, moisture may penetrate into the conductive pattern of the COF package through the solder resist. As a result, an electrical failure such as a short-circuit attributable to an action, such as an ion migration, may occur in the conductive pattern of the COF package.

Accordingly, the COF package including the driver integrated circuit needs to be configured to have a moistureproofing function in order to improve product reliability.

### SUMMARY

Various embodiments are directed to providing a moistureproofing COF package having an improved moistureproofing function by forming a moistureproofing coating layer and a method of fabricating the same.

Also, various embodiments are directed to preventing an electrical failure such as a short-circuit, which may occur in a conductive pattern due to the penetration of moisture through a solder resist.

Furthermore, various embodiments are directed to providing a moistureproofing COF package capable of preventing the penetration of moisture into a semiconductor chip and a solder resist or the solder resist and a method of fabricating the same

In an embodiment, a moistureproofing chip on film (COF) package may include a base film having a conductive pattern formed on one surface thereof and having a solder resist formed on the conductive pattern, and a moistureproofing coating layer formed on the solder resist by coating and configured to block moisture from being delivered to the conductive pattern through the solder resist.

In an embodiment, a method of fabricating a moistureproofing chip on film (COF) package may include forming a solder resist on a conductive pattern, formed on one surface of a base film, so as to cover the conductive pattern, and forming a moistureproofing coating layer on the solder resist by coating in order to block moisture from being delivered to the conductive pattern through the solder resist.

According to the present disclosure, the COF package can have a moistureproofing function by finishing the COF package by using the moistureproofing coating layer.

Furthermore, the moistureproofing COF package of the present disclosure can prevent an electrical failure such as a short-circuit, which may occur in the conductive pattern under the solder resist, by preventing the penetration of moisture through the solder resist.

Furthermore, the moistureproofing COF package of the present disclosure can provide improved product reliability by preventing the penetration of moisture into a chip and the solder resist or the solder resist.

### BRIEF DESCRIPTION OF THE DRAWINGS

FIG. 1 is a side view illustrating a preferred embodiment of a moistureproofing COF package according to the present disclosure.

FIG. 2 is a diagram for describing a method of forming a moistureproofing coating layer of FIG. 1.

FIG. 3 is a diagram for describing another method of forming the moistureproofing coating layer of FIG. 1.

FIG. 4 is a side view illustrating another embodiment of the present disclosure.

### DETAILED DESCRIPTION

Exemplary embodiments will be described below in more detail with reference to the accompanying drawings. The disclosure may, however, be embodied in different forms and should not be constructed as limited to the embodiments set forth herein. Rather, these embodiments are provided so that this disclosure will be thorough and complete, and will fully convey the scope of the disclosure to those skilled in the art. Throughout the disclosure, like reference numerals refer to like parts throughout the various figures and embodiments of the disclosure.

An embodiment of the present disclosure discloses a driver integrated circuit fabricated in the form of a COF package. The driver integrated circuit fabricated in the form of a semiconductor chip is mounted on the COF package. The COF package according to an embodiment of the present disclosure is configured to have a moistureproofing function.

The present disclosure is carried out to implement the moistureproofing function by using a moistureproofing coating layer. The COF package having the moistureproofing function according to the present disclosure is referred to as a “moistureproofing COF package.”

The moistureproofing COF package of the present disclosure has the driver integrated circuit, that is, the semiconductor chip mounted thereon. The semiconductor chip is configured to be supplied with external display data and power and to provide an image signal to a display panel, such as an LCD panel or an LED panel.

The moistureproofing COF package implemented according to an embodiment of the present disclosure is configured to be supplied with the display data and power through a conductive pattern or to supply an image signal to the display panel.

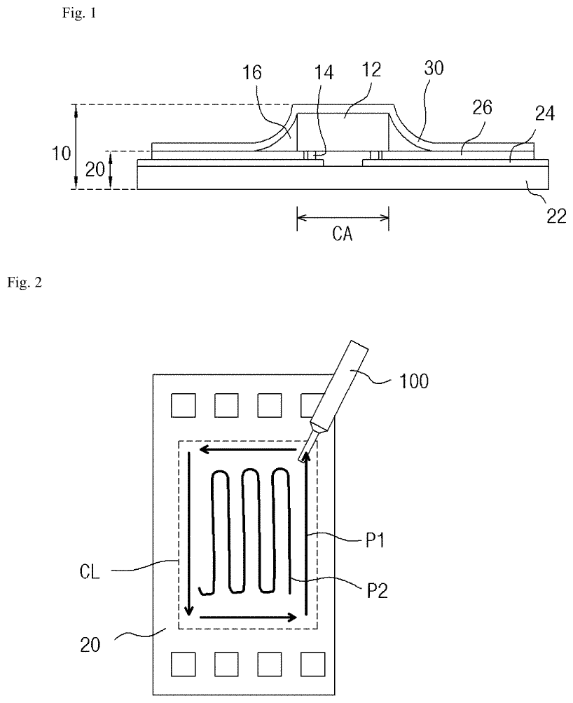

Referring to FIG. 1, a moistureproofing COF package 10 according to the present disclosure includes a base film 20 and a moistureproofing coating layer 30.

The base film 20 includes a conductive pattern 24 and a solder resist 26 on one surface thereof. The solder resist 26 is formed on the conductive pattern 24.

Furthermore, a semiconductor chip 12 is mounted on the one surface of the base film 20. The semiconductor chip 12 may be understood as the driver integrated circuit as described above.

The semiconductor chip 12 includes input pads (not illustrated) for receiving display data and a voltage from the outside and output pads (not illustrated) for outputting source signals and a voltage to a display panel (not illustrated).

The input pads and the output pads may be arranged in side parts facing each other at the bottom of the semiconductor chip 12. Bumps 14 are configured in the input pads and the output pads, respectively. The bumps 14 may be understood as soldering terminals formed for an electrical connection with ends of the conductive pattern 24, which form a routing line on the base film 20.

The base film 20 has a film 22 made of polyimide. The film 22 may have flexibility according to characteristics of a material.

In the base film 20, the conductive pattern 24 is formed on one surface of the film 22. The conductive pattern 24 may be understood as forming routing lines for the input and output of a signal and the supply of power. That is, the conductive pattern 24 may be understood as the routing lines.

A chip area CA in which the semiconductor chip 12 is disposed may be configured in the one surface of the film 22. If the semiconductor chip 12 is disposed in the chip area CA, the bumps 14 may be located within the chip area CA on the one surface of the film 22.

The conductive pattern 24 for routing is formed on the one surface of the film 22 so that the conductive pattern 24 has a preset pattern formed of a thin film for an electrical connection between the semiconductor chip 12 and the display panel (not illustrated).

The conductive pattern 24 has one end extended into the chip area CA for a contact with the bumps 14. Furthermore, the conductive pattern 24 has the other end extended into the side parts of the film 22 for an electrical connection with the display panel. The conductive pattern 24 may be made of a conductive material, such as copper (Cu).

By means of the conductive pattern 24, the bumps 14 of the semiconductor chip 12 may be electrically connected to corresponding ends of the conductive pattern 24 extended into the chip area CA, respectively.

The solder resist 26 is applied on the conductive pattern 24.

The solder resist 26 is formed outside the bumps 14 of the chip area CA, and is applied over the conductive pattern 24 and the film 22 in a way to form a layer. The solder resist 26 is preferably applied so that one end and the other end of the pattern 24 where electrical connections are performed are exposed.

The solder resist 26 configured as described above may be understood as a coating layer playing a role as a protection film for protecting the conductive pattern 24. For example, the solder resist 26 may be formed by the application of ink having an insulating property.

The semiconductor chip 12 is mounted on the one surface of the base film 20. A potting resin 16 may be formed on the side of the semiconductor chip 12. The potting resin 16 is preferably formed to surround the side of the semiconductor chip 12. Accordingly, the potting resin 16 may be understood as being configured to prevent moisture from penetrating through a gap between a lower part of the side of the semiconductor chip 12 and the solder resist 26 and to firmly fix the semiconductor chip 12.

An embodiment of the present disclosure includes the moistureproofing coating layer 30. The moistureproofing coating layer 30 may be attached to the top of the solder resist 26 as illustrated in FIG. 1. The moistureproofing coating layer 30 is configured to cover the top of the solder resist 26, and blocks moisture from being delivered to the solder resist 26. As a result, the moistureproofing coating layer 30 has a function for blocking moisture from being delivered to the conductive pattern 24 through the solder resist 26.

To this end, the moistureproofing coating layer 30 may be configured using a moistureproofing-possible material. The moistureproofing-possible material may be made of polymer series, more preferably, silicon.

The moistureproofing coating layer 30 may be selectively formed in a partial region or the entire region of the top of the base film 20 in order to block moisture from being delivered to the conductive pattern 24 through the solder resist 26.

A case where the moistureproofing coating layer 30 is formed in the entire region of the top of the base film 20 may be understood with reference to FIG. 1. FIG. 1 illustrates that the moistureproofing coating layer 30 is formed to cover the semiconductor chip 12 and the solder resist 26. In this case, the moistureproofing coating layer 30 can block moisture from being delivered to the semiconductor chip 12 in addition to the solder resist 26.

The moistureproofing coating layer 30 may be formed by an encapsulation method, a dispensing method or a jetting method.

An example in which the moistureproofing coating layer 30 is formed is described with reference to FIG. 2.

A supply nozzle 100 may be configured to supply a moistureproofing material for forming the moistureproofing coating layer 30 by using the encapsulation method or the dispensing method. Silicon may be described as being used as the moistureproofing material.

It may be understood that the supply nozzle 100 is supplied with the moistureproofing material from a predetermined moistureproofing material supply source (not illustrated) and linearly supplies the moistureproofing material to the top of the base film 20 by a pumping force.

Furthermore, the supply nozzle 100 may be configured to supply the moistureproofing material while moving in a straight-line direction (arrow P1) or in a zigzag direction (arrow P2) on the top of the base film 20.

The moistureproofing coating layer 30 may be formed by encapsulation using the moistureproofing material linearly discharged through the supply nozzle 100.

The encapsulation includes a step of forming a dam in the outskirts of one surface of the base film 20 by using the moistureproofing material supplied through the supply nozzle 100, a step of additionally applying the moistureproofing material in zigzags on the one surface of the base film 20 within the dam, and a step of evenly diffusing the moistureproofing material and then curing the diffused moistureproofing material at room temperature. As the steps are sequentially performed, the moistureproofing coating layer 30 may be coated with the moistureproofing material.

In this case, the dam formed by the moistureproofing material may be formed along a cutting line CL of the base film 20, for example. The dam may be formed in the outskirts of or within the cutting line CL depending on a fabricator's intention. A direction in which the supply nozzle 100 moves in order to form the dam may be understood to correspond to the arrow P1. The dam having a predetermined height and a predetermined thickness may be formed to surround the base film 20 along the arrow P1. In this case, the cutting line CL may be understood to be a boundary line for separating the moistureproofing COF package for which a fabricating process has been terminated.

If the moistureproofing material is applied in zigzags, it is preferred that an isolated distance between adjacent zigzag lines is maintained to the extent that the moistureproofing material can be uniformly distributed on the base film 20 by subsequent diffusion.

The encapsulation includes diffusing the moistureproofing material supplied to form the dam or supplied in zigzags, as described above, so that the moistureproofing material is distributed on the entirety of the one surface of the base film 20, and then forming the moistureproofing coating layer 30 by natural curing, that is, curing at room temperature.

On the other hand, the dispensing includes a step of applying the moistureproofing material in zigzags on the one surface of the base film 20 and a step of diffusing the moistureproofing material and then hardening the diffused moistureproofing material through a thermal process or ultraviolet radiation. As the steps are sequentially performed, the moistureproofing coating layer 300 is coated with the moistureproofing material.

The dispensing differs from the encapsulation in that the step of forming the dam is excluded and the step of hardening the moistureproofing material is included.

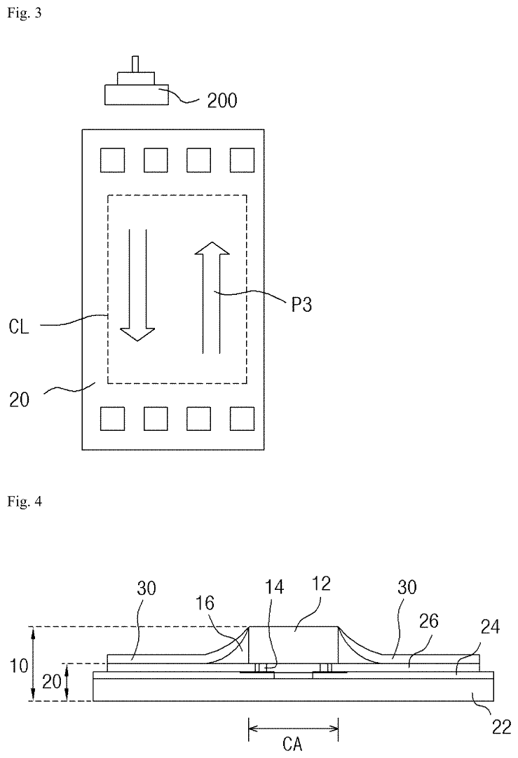

As illustrated in FIG. 3, a jetting module 200 may be configured to supply the moistureproofing material for forming the moistureproofing coating layer 30 by the jetting. It may be understood that the jetting module 200 is supplied with the moistureproofing material from a predetermined moistureproofing material supply source (not illustrated) and jets the moistureproofing material to have a predetermined width on one surface of the base film 20 through jetting holes (not illustrated) having a predetermined jetting width by using a pumping force.

In the case of FIG. 3, the moistureproofing coating layer 30 may be formed by the jetting using the moistureproofing material jetted to have a predetermined width through the jetting module 200.

The jetting may be performed in a predetermined area unit while the jetting module 200 is moved in the width direction of the base film 20 in a stepwise manner. That is, the jetting includes a step of applying the moistureproofing material onto a part or the entirety of the base film 20 and a step of diffusing the moistureproofing material and then hardening the diffused moistureproofing material through a thermal process or ultraviolet radiation. As the steps are sequentially performed, the moistureproofing coating layer 30 may be coated with the moistureproofing material.

An embodiment of the present disclosure may form the moistureproofing coating layer 30 by applying the encapsulation, the dispensing and the jetting solely or complexly. A method of forming the moistureproofing coating layer 30 may be selected depending on a fabricator's intention.

An embodiment of the present disclosure may form the moistureproofing coating layer 30 to cover an area restricted by the top of the solder resist 26 as illustrated in FIG. 4 by applying the encapsulation, the dispensing and the jetting solely or complexly.

In this case, the moistureproofing coating layer 30 can block moisture from being delivered to the solder resist 26.

Accordingly, the present disclosure can implement the moistureproofing COF package by using the moistureproofing coating layer, and can prevent the penetration of moisture through the solder resist because the moistureproofing coating layer can block moisture from being delivered to the solder resist, that is, an underlying layer.

Accordingly, the present disclosure can prevent an electrical failure, such as al short-circuit, which may occur in the conductive pattern under the solder resist due to moisture.

Furthermore, the present disclosure can provide improved product reliability by preventing the penetration of moisture into the chip and the solder resist or the solder resist.

While various embodiments have been described above, it will be understood to those skilled in the art that the embodiments described are by way of example only. Accordingly, the disclosure described herein should not be limited based on the described embodiments.

What is claimed is:

1. A moistureproofing chip on film (COF) package comprising:
a base film having a conductive pattern formed on one surface thereof and having a solder resist formed on the conductive pattern; and
a moistureproofing coating layer formed on the solder resist by coating and configured to block moisture from being delivered to the conductive pattern through the solder resist.

2. The moistureproofing COF package of claim 1, wherein the moistureproofing coating layer has a polymer-series material.

3. The moistureproofing COF package of claim 1, wherein the moistureproofing coating layer has a silicon material.

4. The moistureproofing COF package of claim 1, wherein:
a semiconductor chip electrically connected to the conductive pattern is mounted on the one surface of the base film, and
the moistureproofing coating layer is formed to cover the semiconductor chip and the solder resist.

5. The moistureproofing COF package of claim 1, wherein the moistureproofing coating layer is formed to cover an area restricted by a top of the solder resist.

6. The moistureproofing COF package of claim 1, wherein the moistureproofing coating layer is formed by a method selected among dispensing, encapsulation and jetting.

7. A method of fabricating a moistureproofing chip on film (COF) package, comprising:
forming a solder resist on the conductive pattern, formed on one surface of a base film, in order to cover the conductive film; and
forming a moistureproofing coating layer on the solder resist by coating in order to block moisture from being delivered to the conductive pattern through the solder resist.

8. The method of claim 7, wherein the moistureproofing coating layer is formed using a silicon material.

9. The method of claim 7, further comprising mounting, on the one surface of the base film, a semiconductor chip electrically connected to the conductive pattern,
wherein the moistureproofing coating layer is formed to cover the semiconductor chip and the solder resist.

10. The method of claim 7, wherein the moistureproofing coating layer is formed to cover an area restricted by a top of the solder resist.

11. The method of claim 7, wherein:
the moistureproofing coating layer is formed by encapsulation using a moistureproofing material discharged through a supply nozzle, and
the encapsulation comprises steps of:
forming a dam in an outskirts of the one surface of the base film by using the moistureproofing material;
applying the moistureproofing material in zigzags on the one surface of the base film within the dam; and
diffusing the moistureproofing material and then curing the diffused moistureproofing material at room temperature.

12. The method of claim 7, wherein:
the moistureproofing coating layer is formed by dispensing using a moistureproofing material discharged through a supply nozzle, and
the dispensing comprising:
applying the moistureproofing material in zigzags on the one surface of the base film; and
diffusing the moistureproofing material and then hardening the diffused moistureproofing material through a thermal process or ultraviolet radiation.

13. The method of claim 7, wherein:
the moistureproofing coating layer is formed by jetting using a moistureproofing material jetted from a jetting module having jetting holes having a predetermined jetting width, and
the jetting comprises:
applying the moistureproofing material to a part or the entirety of the base film by jetting the moistureproofing material in a predetermined area unit while moving the jetting module in a width direction of the base film in a stepwise manner; and
diffusing the moistureproofing material and then hardening the diffused moistureproofing material through a thermal process or ultraviolet radiation.
